(19) United States
(12) Patent Application Publication
(10) Pub. No.: US 2025/0385131 A1
(43) Pub. Date: Dec. 18, 2025

(54) METHODS OF MANUFACTURING AN ELECTRONIC CIRCUIT TO PREVENT OXIDATION OR NITRIDATION OF A METAL LAYER DURING MANUFACTURING

(71) Applicant: Micron Technology, Inc., Boise, ID (US)

(72) Inventor: Everett Allen McTeer, Eagle, ID (US)

(21) Appl. No.: 19/226,843

(22) Filed: Jun. 3, 2025

Related U.S. Application Data
(60) Provisional application No. 63/658,996, filed on Jun. 12, 2024.

(51) Int. Cl. H01L 21/768; H01L 21/3205

(52) U.S. Cl. CPC H01L 21/7685; H01L 21/32053

(57) ABSTRACT

A method includes forming a tier stack of an electronic circuit, the tier stack including a plurality of tiers. A tier includes multiple alternating conductive and dielectric layers. The method further includes exposing a conductive layer by etching one or more dielectric layers. The method further includes forming a protective layer on the conductive layer. The conductive layer includes a metal. The protective layer includes the metal.

### RELATED APPLICATION

This application claims the benefit of U.S. Provisional Patent Application No. 63/658,996, filed June 12, 2024, the entire content of which is incorporated by reference herein.

### TECHNICAL FIELD

Embodiments of the disclosure relate generally to memory sub-systems, and more specifically, relate to methods of manufacturing an electronic circuit to prevent oxidation or nitridation of a metal layer during manufacturing.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIGS. 1A-I are schematic representations illustrating a method of manufacturing an electronic circuit to prevent oxidation or nitridation of a metal layer during manufacturing, in accordance with some embodiments of the present disclosure.

FIGS. 2A-C are flow diagrams of example methods of manufacturing an electronic circuit to prevent oxidation or nitridation of a metal layer during manufacturing, in accordance with some embodiments of the present disclosure.

FIG. 3A illustrates an example computing system that includes a memory sub-system in accordance with some embodiments of the present disclosure.

FIG. 3B is a block diagram of a memory device in communication with a memory sub-system controller of a memory sub-system, according to an embodiment.

### DETAILED DESCRIPTION

Aspects of the present disclosure are directed to methods of manufacturing an electronic circuit (e.g., a memory array) prevent oxidation or nitridation of a metal layer during manufacturing of the electronic circuit . Storage devices such as solid-state drives (SSDs) may incorporate 3-dimensional (3D) NAND flash memory technology. Traditional NAND flash memory stores data in a 2-dimensional (2D) structure, where memory cells are laid out on a single layer. 3-dimensional (3D) NAND instead stacks memory cells vertically in multiple layers (hence the “3D” designation). Such vertical stacking allows for increased storage densities and greater storage capacity in a comparatively smaller physical footprint when compared to planar NAND. A key advantage of 3D NAND is its ability to continue increasing storage capacities while maintaining or even improving performance and reliability. 3D NAND technology has enabled the development of SSDs with larger capacities, faster speeds, and lower costs per unit of storage.

A 3D NAND device includes multiple memory cells stacked vertically in multiple tiers. In order to achieve higher storage capacities and/or improve performance of the device, the number of tiers within a single memory device may be increased, thus allowing for higher-capacity storage devices. However, the increase in the number of tiers also increases the overall height of the 3D NAND structure. To limit the height of the 3D NAND structure, the thickness of each tier can be decreased.

Each tier in a 3D NAND structure can include multiple layers. For example, a tier can include an oxide layer (e.g., a metalloid oxide layer such as a silicon-oxide layer), a nitride layer (e.g., a metalloid nitride layer such as a silicon-nitride layer), and/or a metal layer. To increase the number of tiers in a 3D NAND structure without increasing the overall height of the structure, the thickness of each layer in the tiers making up the 3D NAND structure can be decreased. However, as the layer thickness is decreased, the accuracy which etch operations are performed to access layers in each tier (e.g., such as the metal layer) must also increase. For example, an etch operation is often performed to etch down to a metal layer of a tier to access the metal layer. Ideally, the etch operation will stop on the metal layer. However, if the metal layer is too thin, the etch operation may continue past (e.g., through) the metal layer and may continue to the next metal layer of the next lower tier. This “over-shoot” of the etch operation will electrically short the two metal layers together, making the two metal layers unusable for data storage.

Several factors affect the thickness of a metal layer in a tier. First, is the nominal thickness of the metal layer. As discussed herein above, to increase the number of tiers in a 3D NAND structure without increasing the overall height of the structure, the thickness of each layer in the tiers making up the 3D NAND structure can be decreased. The thickness of the metal layer of each tier may be decreased to increase the density of memory cells in the 3D NAND structure. Second, the metal layer may be unintentionally degraded (e.g., etched, oxidized, nitridized, partially removed, etc.) by process operations performed to manufacture the 3D NAND structure. For example, reactive processes such as etch processes or cleaning processes may attack the exposed metal layer, causing the metal layer to react with the process chemistries and become thin. The metal layer can oxidize or nitridize. The oxidized or nitridized metal can be removed during a cleaning process or etch process that is to remove oxides, thinning the remaining metal layer. Repetitions of oxidation or nitridation and removal of the metal layer can cause the metal layer to be undesirably thin. When the metal layer becomes too thin or is removed completely, later metal deposition processes can cause the metal layer to be electrically shorted, rendering the metal layer unusable for memory storage.

Aspects of the present disclosure can address the deficiencies described above and other challenges by providing methods of manufacturing a memory array to prevent oxidation of a metal layer during the manufacturing. In some embodiments, a protective layer is formed on a metal layer in a tier stack such as an oxidation-resistant layer and/or a nitridation-resistant layer, etc. The protective layer may be formed by causing a metalloid such as silicon to react with the metal layer to form a protective metal-silicide layer (e.g., a metal-metalloid layer, etc.) on the metal layer. Alternatively, the protective layer may be formed by causing a metal (e.g., a different metal) to react with the metal layer to form a protective metal alloy layer on the metal layer. In some embodiments, the metal-silicide layer is intended to protect the metal layer while additional process operations are performed. For example, the metal-silicide layer may prevent process chemicals from reacting with the metal. The metal-silicide layer may prevent the metal layer from oxidizing, nitridizing, and/or otherwise degrading during the additional process operations. By preventing oxidation, nitridation, and/or degradation of the metal layer, formation of undesirable electrical shorts can be prevented between metal layers of adjacent tiers because subsequent etch operations may stop on the metal layer without “over-shooting” the metal layer into the next metal layer. In some embodiments, the metal-silicide layer is formed by depositing a silicon layer on the metal layer after an etch operation is performed to access the metal layer. The silicon and/or metal layer may then be annealed to cause the metal to react with the silicon, forming the metal-silicide. In some embodiments, the metal-silicide layer is formed by introducing a silicon-containing precursor, thus causing the precursor to react with the metal layer to form the metal-silicide layer.

Advantages of the present disclosure include, for example, improved 3D NAND structures having fewer unintentional and undesirable shorts between metal layers. By using the methods described herein, each of the metal layers in a tier stack can be protected from chemistries used in subsequent process operations so that the metal layers are not oxidized, nitridized, and/or otherwise degraded during subsequent processing operations. The integrity of the metal layers may thus be maintained so that the 3D NAND structure can effectively utilize all the metal layers for data storage. Moreover, by reducing the number of unintentional and undesirable shorts between metal layers, the performance of a memory sub-system can be improved, leading to faster memory operations and/or decreased latency.

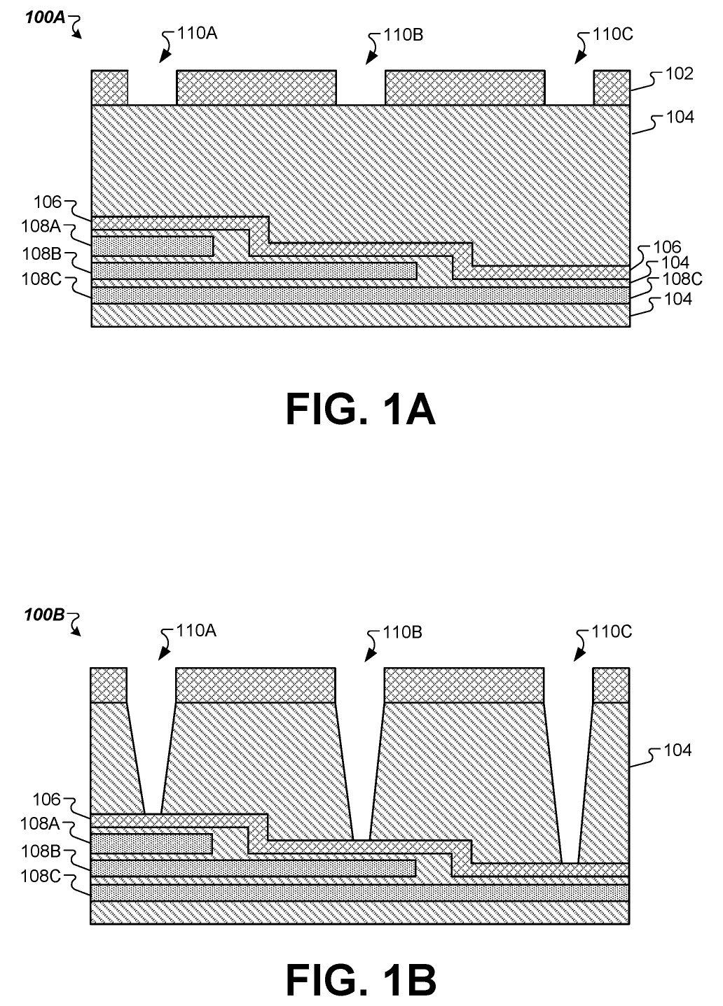

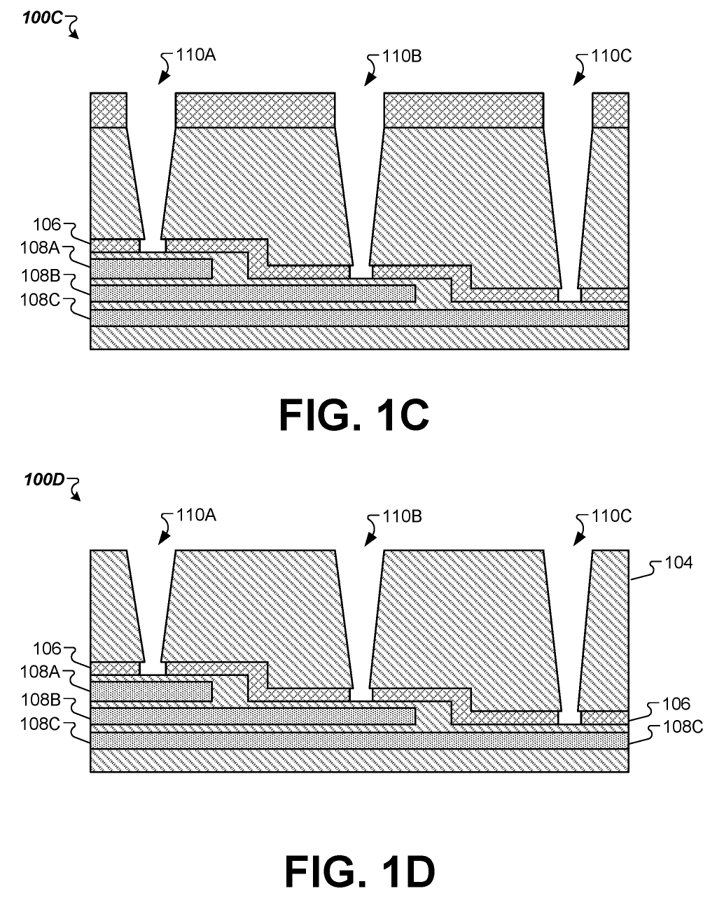

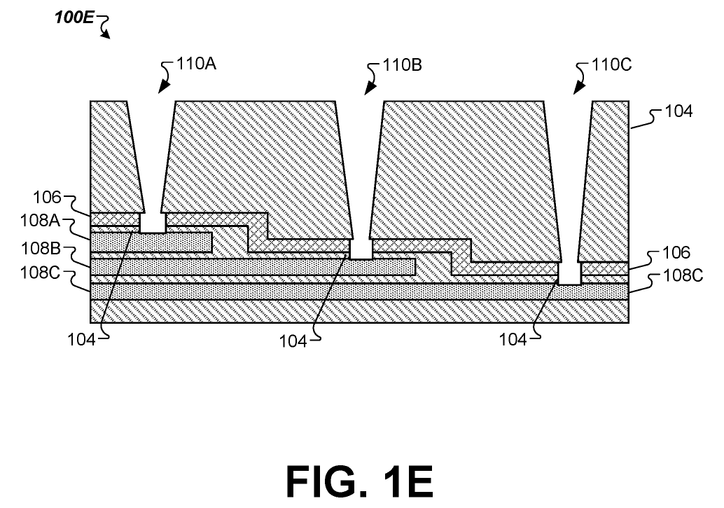

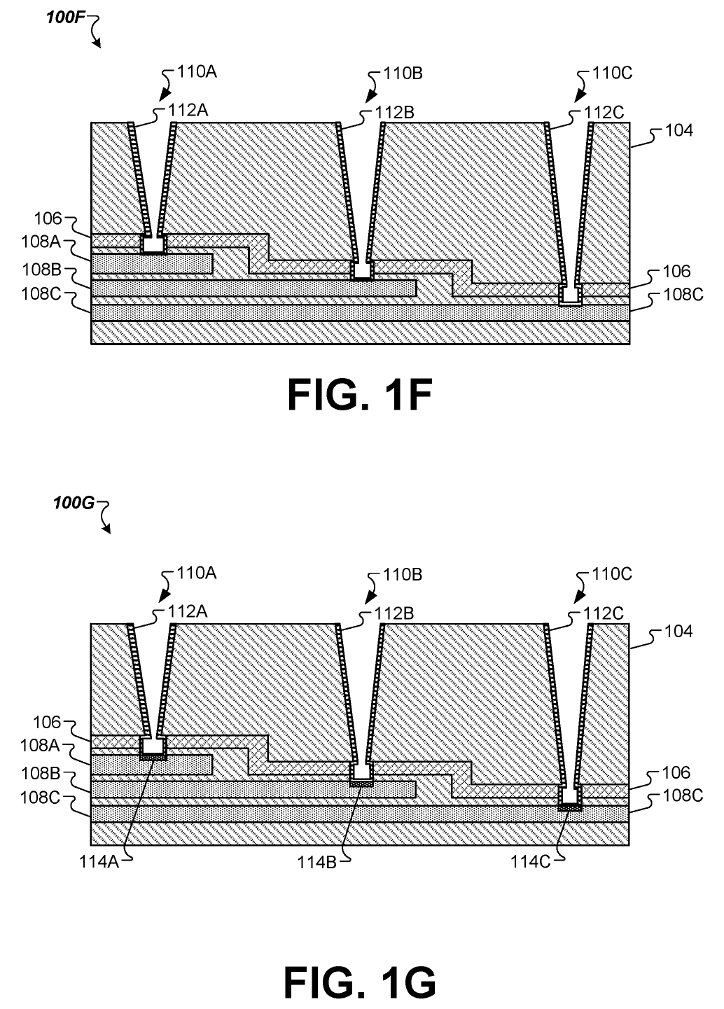

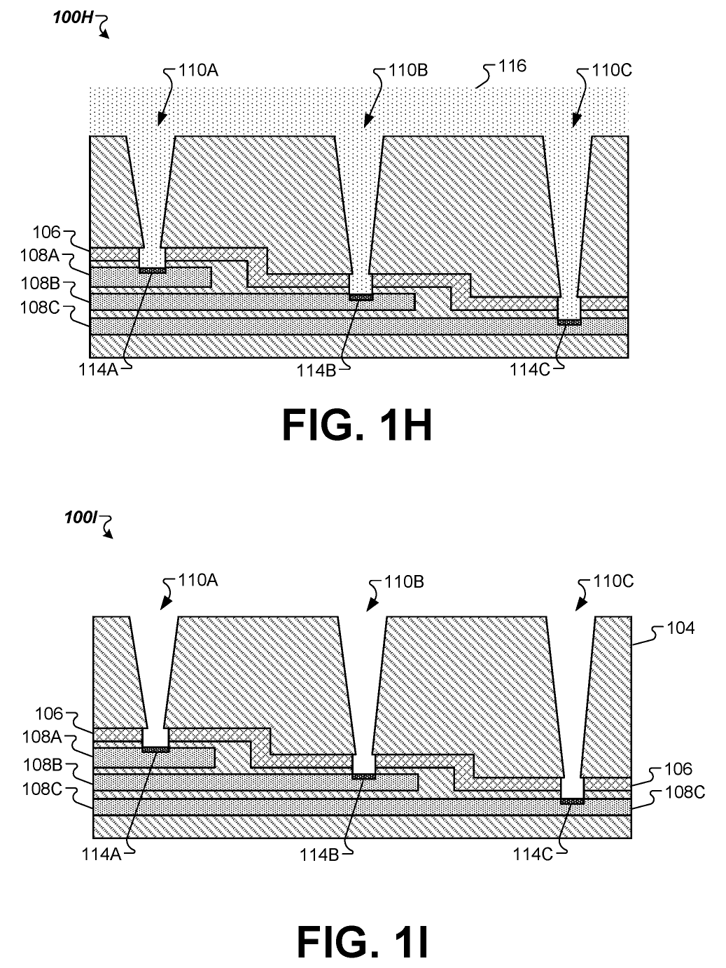

FIGS. 1A-H are schematic representations illustrating a method of manufacturing an electronic circuit (e.g., a memory array) to prevent oxidation or nitridation of a metal layer during manufacturing, in accordance with some embodiments of the present disclosure. In some embodiments, each of FIGS. 1A-H illustrate a manufacturing operation for manufacturing a memory array as described herein.

Referring to FIG. 1A, a representation of a first operation 100A is shown. In some embodiments, a tier stack is formed. The tier stack may have multiple tiers. A tier may be formed by multiple layers. For example, a tier may include an oxide layer 104 (e.g., a metalloid oxide layer such as a silicon oxide layer), a nitride layer 106 (e.g., a metalloid nitride layer such as a silicon nitride layer), and/or a metal layer 108 (e.g., metal layer 108A, 108B, or 108C). In some embodiments, metal layers 108 are conductive layers. For example, and in some embodiments, metal layers 108 are made of molybdenum, a molybdenum alloy, tungsten, and/or a tungsten alloy, etc. In some embodiments, the oxide layer 104 and/or the nitride layer 106 are dielectric layers (e.g., electrically insulating layers) to electrically insulate the metal layers 108 (e.g., to insulate the metal layers 108 from each other, etc.). Illustrated in FIG. 1A, three tiers are shown, although more tiers are possible. In some embodiments, each of the metal layers 108 forms a conductive line in the tier stack. The conductive lines may be wordlines, such as in a memory array.

In some embodiments, the stack of layers is formed by multiple deposition processes. For example, a first deposition process may be performed to deposit a first oxide layer 104, a second deposition process may be performed to deposit a first metal layer 108 (e.g., metal layer 108C), a third deposition process may be performed to deposit a second oxide layer 104, a fourth deposition process may be performed to deposit a second metal layer 108 (e.g., metal layer 108B), a fifth deposition process may be performed to deposit a third oxide layer 104, a sixth deposition process may be performed to deposit a third metal layer 108 (e.g., metal layer 108A), and a seventh deposition process may be performed to deposit a fourth oxide layer 104. In some embodiments, an eighth deposition process may be performed to deposit a nitride layer 106 on top of the stack of layers and a ninth deposition process may be performed to deposit a fifth oxide layer 104, etc.

In some embodiments, the nitride layer 106 forms a stair-step profile. For example, and in some embodiments, the nitride layer 106 is disposed above metal layer 108A, 108B, and 108C. Metal layer 108A may extend laterally only through a first portion of the stack. Metal layer 108B may extend laterally only through at least a second portion of the stack but may extend further than metal layer 108A. Metal layer 108C may extend laterally only through at least a second portion of the stack but may extend further than metal layers 108A and 108B. In some embodiments, the ends of the metal layers 108 form a stair-step profile. The nitride layer 106 may form a stair-step profile that substantially matches the stair-step profile of the metal layers 108. In some embodiments, an oxide layer 104 is deposited on top of the nitride layer 106.

In some embodiments, a mask layer 102 is deposited on top of the top oxide layer 104, such as by chemical vapor deposition (CVD) or physical vapor deposition (PVD). The mask layer 102 may be a protective layer that is to define patterns for etching operations. The mask layer 102 may ensure the underlying layers remain intact while specific areas are exposed for further processing. In some embodiments, the mask layer 102 is composed of a mask material, such as photoresist or carbon. In some embodiments, the mask material is patterned (e.g., by photolithography, etc.) to form a patterned mask material layer (e.g., mask layer 102). In some embodiments, mask layer 102 forms pattern areas 110 (e.g., 110A, 110B, 110C). The regions beneath the pattern areas 110 may be etched during processing operations described herein below. In some embodiments, mask layer 102 is made of a material resistant to etching chemistries. The pattern areas 110 may be formed by photolithography to remove portions of the mask layer 102 that correspond to the pattern areas 110.

Referring to FIG. 1B, a representation of a second operation 100B is shown. In some embodiments, an etch operation is performed to remove portions of the oxide layer 104 beneath the pattern areas 110. In some embodiments, the etch operation is performed by introducing process chemistries to etch the oxide layer 104. Such process chemistries can include hydrofluoric acid (HF), phosphoric acid (H₃PO₄), hot potassium hydroxide (KOH), and/or tetramethylammonium hydroxide (TMAH). In some embodiments, the etch operation is a dry etch operation performed using process chemistries such as CF₄/O₂/Ar, C₄F₈/O₂/Ar, SF₆, NF₃, etc. In some embodiments, the etch operation is performed until the top of the nitride layer 106 is exposed.

Referring to FIG. 1C, a representation of a third operation 100C is shown. In some embodiments, an etch operation is performed to remove portions of the nitride layer 106. In some embodiments, the etch operation is performed by introducing process chemistries to etch the nitride layer 106. Such process chemistries can include hot phosphoric acid (H₃PO₄), hydrofluoric acid (HF), phosphoric acid with ammonia or ammonium hydroxide, and/or tetramethylammonium hydroxide (TMAH). In some embodiments, the etch operation is a dry etch operation performed using process chemistries such as CF₄/O₂/Ar, C₄F₈/O₂/Ar, SF₆, NF₃, etc. In some embodiments, portions of the nitride layer 106 beneath the pattern areas 110 are removed by the etch operation.

Referring to FIG. 1D, a representation of a fourth operation 100D is shown. In some embodiments, a strip and/or a clean operation is performed to remove the mask layer 102 and/or to clean the etched regions of the tier stack.

Referring to FIG. 1E, a representation of a fifth operation 100E is shown. In some embodiments, an etch operation is performed to etch the oxide layers 104 between the nitride layer 106 and each of the metal layers 108A-C. For example, the etch operation is performed to etch the oxide layer 104 between the nitride layer 106 and the metal layer 108A, to etch the oxide layer 104 between the nitride layer 106 and the metal layer 108B, and to etch the oxide layer 104 between the nitride layer 106 and the metal layer 108C. In some embodiments, the etch operation is performed to expose a portion of the top of the metal layers 108.

Referring to FIG. 1F, a representation of a sixth operation 100F is shown. In some embodiments, a silicon layer is deposited on the etched regions of the oxide layer(s) 104, the nitride layer 106, and/or the exposed regions of metal layers 108. For example, and in some embodiments, a silicon layer 112A is deposited on the exposed portions of metal layer 108A, nitride layer 106, and oxide layer 104 corresponding to pattern region 110A. A silicon layer 112B is deposited on the exposed portions of metal layer 108B, nitride layer 106, and oxide layer 104 corresponding to pattern region 110B. A silicon layer 112C is deposited on the exposed portions of metal layer 108C, nitride layer 106, and oxide layer 104 corresponding to pattern region 110C. In some embodiments, the silicon layer is poly-silicon (e.g., polycrystalline silicon).

Referring to FIG. 1G, a representation of a seventh operation 100G is shown. In some embodiments, the silicon layer 112 is annealed to cause the silicon layer 112 to react with the metal layers 108 to form a metal-silicide layer on top of the exposed portions of the metal layers 108. For example, the silicon layer 112 may be heated, causing the silicon layer 112 to react with the metal layers 108. A portion of the silicon layer 112A may react with the metal layer 108A to form a metal-silicide layer 114A on top of the metal layer 108A. A portion of the silicon layer 112B may react with the metal layer 108B to form a metal-silicide layer 114B on top of the metal layer 108B. A portion of the silicon layer 112C may react with the metal layer 108C to form a metal-silicide layer 114C on top of the metal layer 108C.

In some embodiments, where the metal layers 108 are made of molybdenum, the silicon layer 112 may react with the molybdenum to form a molybdenum silicide layer (e.g., metal silicide layers 114 may be molybdenum silicide layers, etc.). In some embodiments, where the metal layers 108 are made of tungsten, the silicon layer 112 may react with the tungsten to form a tungsten silicide layer (e.g., metal silicide layers 114 may be tungsten silicide layers, etc.).

Referring to FIG. 1H, a representation of an eighth operation 100H is shown. In some embodiments, operation 100H may be performed as an alternative to operations 100F and 100G. In some embodiments, a metalloid-containing precursor is introduced to the metal layers 108. For example, and in some embodiments, a silicon-containing precursor 116 is introduced to the metal layers 108. In some embodiments, the silicon-containing precursor 116 reacts with the metal layers 108 to form a metal-silicide layer on top of the metal layers. The silicon-containing precursor 116 may react with metal layer 108A to form a metal-silicide layer 114A on top of the metal layer 108A. The silicon-containing precursor 116 may react with metal layer 108B to form a metal-silicide layer 114B on top of the metal layer 108B. The silicon-containing precursor 116 may react with metal layer 108C to form a metal-silicide layer 114C on top of the metal layer 108C.

In some embodiments, where the metal layers 108 include molybdenum, the silicon-containing precursor 116 may react with the molybdenum to form a molybdenum silicide layer (e.g., metal silicide layers 114 may be molybdenum silicide layers, etc.). In some embodiments, where the metal layers 108 are made of tungsten, the silicon-containing precursor 116 may react with the tungsten to form a tungsten silicide layer (e.g., metal silicide layers 114 may be tungsten silicide layers, etc.).

Referring to FIG. 1I, a representation of a ninth operation 100I is shown. In some embodiments, a cleaning operation may be performed to remove unreacted silicon. For example, unreacted portions of the silicon layer 112 (of operations 100F.1 and 100F.2) and/or unreacted silicon from the silicon-containing precursor 116 (of operation 100G) may be removed so that the metal-silicide layers 114 are left on top of the metal layers 108. In some embodiments, the metal-silicide layers 114 are protective layers (e.g., oxidation-resistant layers, nitridation-resistant layers, etc.) that are to protect the metal layers 108 while one or more additional process operations such as one or more oxidizing operations, one or more nitridizing operations, etc. are performed. The one or more additional process operations may be to form one or more contacts for electronically accessing the metal layers 108.

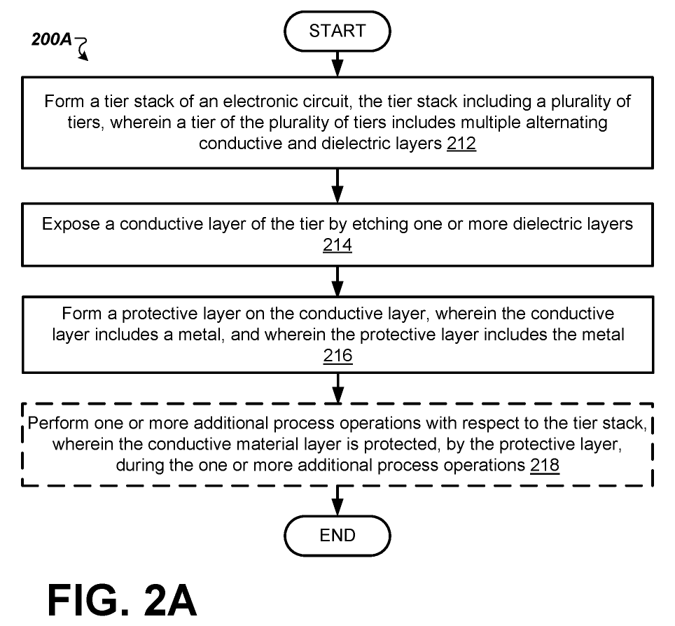

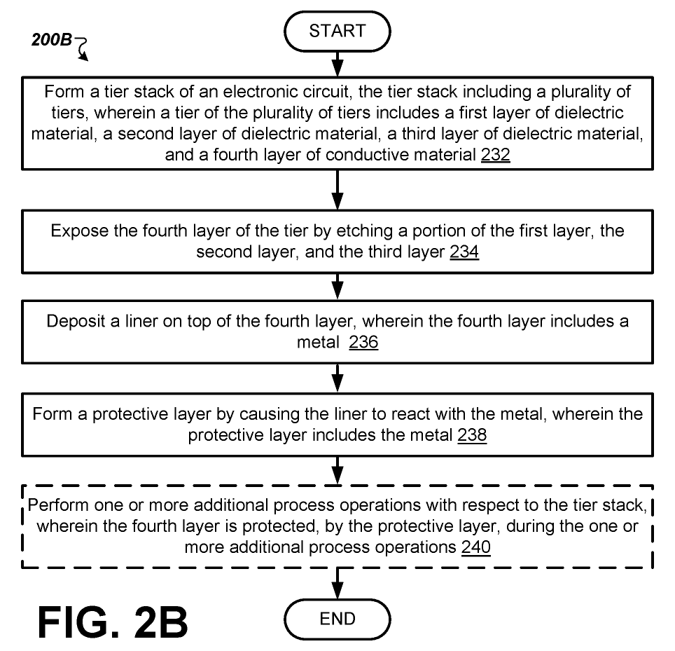

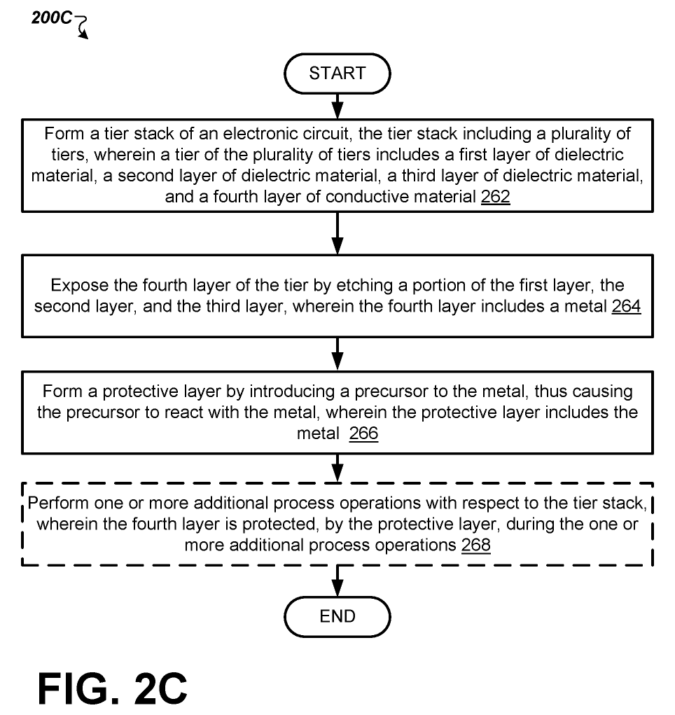

FIGS. 2A-C are flow diagrams of example methods of manufacturing an electronic circuit (e.g., a memory array) to prevent oxidation or nitridization of a metal layer during manufacturing, in accordance with some embodiments of the present disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Referring to FIG. 2A, a flow diagram of an example method 200A for manufacturing a memory array to prevent oxidation or nitridation of a metal layer during manufacturing is shown, in accordance with some embodiments of the present disclosure. At block 212, a tier stack of an electronic circuit is formed, the tier stack including a plurality of tiers. In some embodiments, the electronic circuit is a memory array such as a flash memory array, a 3D NAND memory array, etc. A tier of the tier stack may include multiple alternating conductive and insulating layers. For example, the tier may include a dielectric metalloid oxide layer (e.g., a silicon oxide layer), a conductive metal layer, and/or a dielectric metalloid nitride layer (e.g., a silicon oxide layer). In some embodiments, the conductive metal layer is made of a conductive metal such as molybdenum, a molybdenum alloy, tungsten, or a tungsten alloy, etc. In some embodiments, the tiers are formed via multiple deposition processes, one on top of the other, to form the tier stack. In some embodiments, the plurality of tiers form a stair-step profile.

At block 214, a conductive layer of the tier is exposed by etching one or more dielectric layers. In some embodiments, one or more dielectric layers are etched to expose the top of a conductive layer of the tier. For example, a metalloid oxide layer and a metalloid nitride layer of the tier may be etched to expose a molybdenum layer of the tier.

At block 216, a protective layer (e.g., an oxidation-resistant layer or a nitridation-resistant layer, etc.) is formed on the conductive layer of the tier. In some embodiments, the conductive layer includes a metal. For example, and in some embodiments, the conductive layer is the metal layer. In some embodiments, the protective layer includes the metal. For example, the metal layer may be made of molybdenum and the protective layer may include molybdenum. In some embodiments, the protective layer is formed by depositing a silicon layer (e.g., a polycrystalline silicon layer) on the exposed metal (e.g., exposed by the etch operation at block 214) and causing the silicon to react with the metal by an annealing process to form a metal-silicide. In some embodiments, the protective is formed by introducing a silicon-containing precursor to the exposed metal and causing the silicon-containing precursor to react with the metal to form a metal-silicide. The metal silicide may form the protective layer. In some examples, where the metal layer is a molybdenum layer, the silicon layer or the silicon-containing precursor may react with the exposed molybdenum to form a protective molybdenum silicide layer.

At block 218, one or more additional process operation are performed with respect to the tier stack. In some embodiments, the additional processes include oxidizing operations and/or nitridizing operations. The conductive material layer (e.g., the metal layer) of the tier may be protected by the protective layer (e.g., the metal-silicide) while the one or more additional process operations are performed. For example, the protective layer may protect the metal layer from oxidizing during one or more oxidizing operations. In another example, the protective layer may protect the metal layer from nitridizing during one or more nitridizing operations. The one or more oxidizing operations and/or nitridizing operations may be harmful to the metal layer if it were not for the protective layer. The one or more additional process operations may be for forming one or more contacts for electronically accessing the metal layer.

Referring to FIG. 2B, a flow diagram of an example method 200B for manufacturing a memory array to prevent oxidation of a metal layer during manufacturing is shown, in accordance with some embodiments of the present disclosure. At block 232, a tier stack of an electronic circuit is formed, the tier stack including a plurality of tiers. In some embodiments, the electronic circuit is a memory array such as a flash memory array, a 3D NAND memory array, etc. In some embodiments, the tier includes a first layer of dielectric material, a second layer of dielectric material, a third layer of dielectric material, and a fourth layer of conductive material. In some embodiments, the first layer, the second layer, and/or the third layer are dielectric layers (e.g., electrically insulating layers) while the fourth layer is an electrically conductive layer. For example, the fourth layer may be a metal layer (e.g., such as a molybdenum layer, etc.) and the first layer, second layer, and third layer may be metalloid oxide layers and/or metalloid nitride layers. In some embodiments, the tiers are formed via multiple deposition processes, one on top of the other, to form the tier stack. In some embodiments, the plurality of tiers form a stair-step profile.

At block 234, the fourth layer of the tier is exposed by etching a portion of the first layer, the second layer, and the third layer of the tier. In some embodiments, one or more etch operations are performed to etch through the first layer, the second layer, and/or the third layer to expose the fourth layer. For example, a first etch operation may be performed to etch a top metalloid oxide layer, a second etch operation may be performed to etch a metalloid nitride layer, and a third etch operation may be performed to etch an intermediate metalloid oxide layer, thus exposing the metal layer situated beneath the intermediate metalloid oxide layer.

At block 236, a liner is deposited on top of the fourth layer. The fourth layer may include a metal (e.g., the fourth layer is a metal layer). In some embodiments, the liner is a metalloid layer (e.g., a polycrystalline silicon layer). In some embodiments, the fourth layer is made of molybdenum, a molybdenum alloy, tungsten, or a tungsten alloy.

At block 238, an protective layer is formed by causing the liner to react with the metal. In some embodiments, the protective layer includes the metal. In some embodiments, the liner is caused to react with the metal by annealing. For example, the silicon layer and the tier stack may be heated so that the metal and the liner react to form a protective metal-silicide. The metal-silicide may form the protective layer. In another example, where the metal layer is a molybdenum layer, during the annealing process, the silicon layer may react with the exposed molybdenum to form a protective molybdenum silicide layer.

At block 240, one or more additional process operation are performed with respect to the tier stack. In some embodiments, the additional processes include oxidizing operations. The fourth layer (e.g., the metal layer) of the tier may be protected by the protective layer (e.g., the metal-silicide) while the one or more additional process operations are performed. For example, the protective layer may protect the metal layer from oxidizing during one or more oxidizing operations. In another example, the protective layer may protect the metal layer from nitridizing during one or more nitridizing operations. The one or more oxidizing operations and/or nitridizing operations may be harmful to the metal layer if it were not for the protective layer. The one or more additional process operations may be for forming one or more contacts for electronically accessing the metal layer.

Referring to FIG. 2C, a flow diagram of an example method 200C for manufacturing a memory array to prevent oxidation or nitridation of a metal layer during manufacturing is shown, in accordance with some embodiments of the present disclosure. At block 262, a tier stack of an electronic circuit is formed, the tier stack including a plurality of tiers. In some embodiments, the electronic circuit is a memory array such as a flash memory array, a 3D NAND memory array, etc. In some embodiments, the tier includes a first layer of dielectric material, a second layer of dielectric material, a third layer of dielectric material, and a fourth layer of conductive material. In some embodiments, the first layer, the second layer, and/or the third layer are dielectric layers (e.g., electrically insulating layers) while the fourth layer is an electrically conductive layer. For example, the fourth layer may be a metal layer (e.g., such as a molybdenum layer, etc.) and the first layer, second layer, and third layer may be metalloid oxide layers and/or metalloid nitride layers. In some embodiments, the tiers are formed via multiple deposition processes, one on top of the other, to form the tier stack. In some embodiments, the plurality of tiers form a stair-step profile.

At block 264, the fourth layer of the tier is exposed by etching a portion of the first layer, the second layer, and the third layer of the tier. In some embodiments, one or more etch operations are performed to etch through the first layer, the second layer, and/or the third layer to expose the fourth layer. For example, a first etch operation may be performed to etch a top metalloid oxide layer, a second etch operation may be performed to etch a metalloid nitride layer, and a third etch operation may be performed to etch an intermediate metalloid oxide layer, thus exposing the metal layer situated beneath the intermediate metalloid oxide layer.

At block 266, an protective layer is formed by introducing a precursor to the metal, thus causing the precursor to react with the metal. In some embodiments, the protective layer includes the metal. In some embodiments, the precursor is a metalloid-containing precursor such as a silicon-containing precursor. The precursor may react with the metal to form a protective metal-silicide layer. For example, and in some embodiments, where the metal layer is made of molybdenum, the silicon-containing precursor may react with the molybdenum to form a protective molybdenum silicide layer.

At block 268, one or more additional process operation are performed with respect to the tier stack. In some embodiments, the additional processes include oxidizing operations and/or nitridizing operations. The fourth layer (e.g., the metal layer) of the tier may be protected by the protective layer (e.g., the metal-silicide) while the one or more additional process operations are performed. For example, the protective layer may protect the metal layer from oxidizing during one or more oxidizing operations. In another example, the protective layer may protect the metal layer from nitridizing during one or more nitridizing operations. The one or more oxidizing operations and/or nitridizing operations may be harmful to the metal layer if it were not for the protective layer. The one or more additional process operations may be for forming one or more contacts for electronically accessing the metal layer.

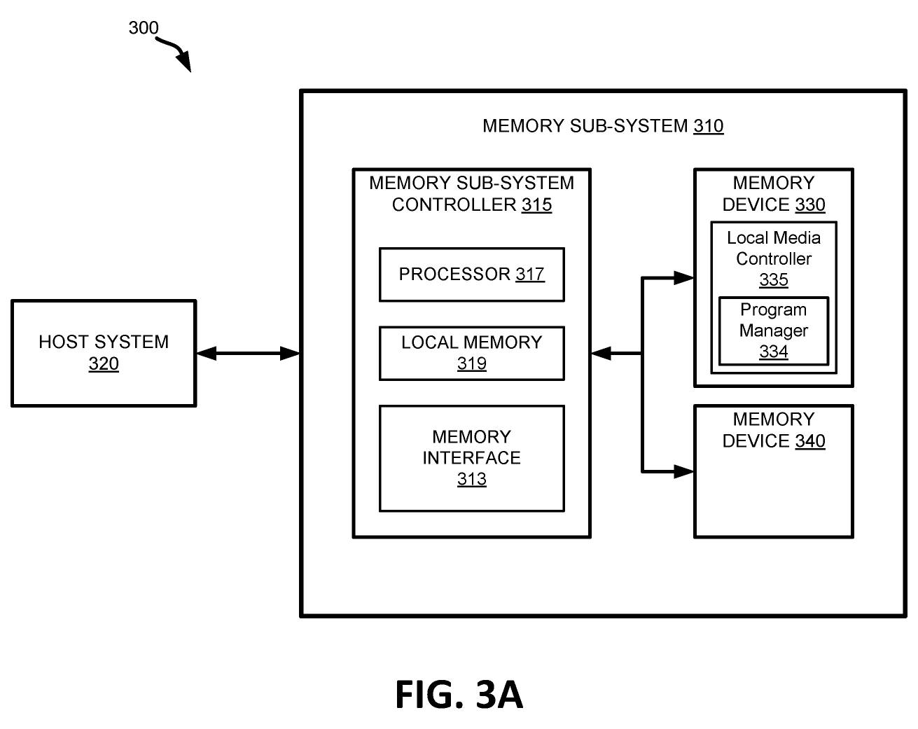

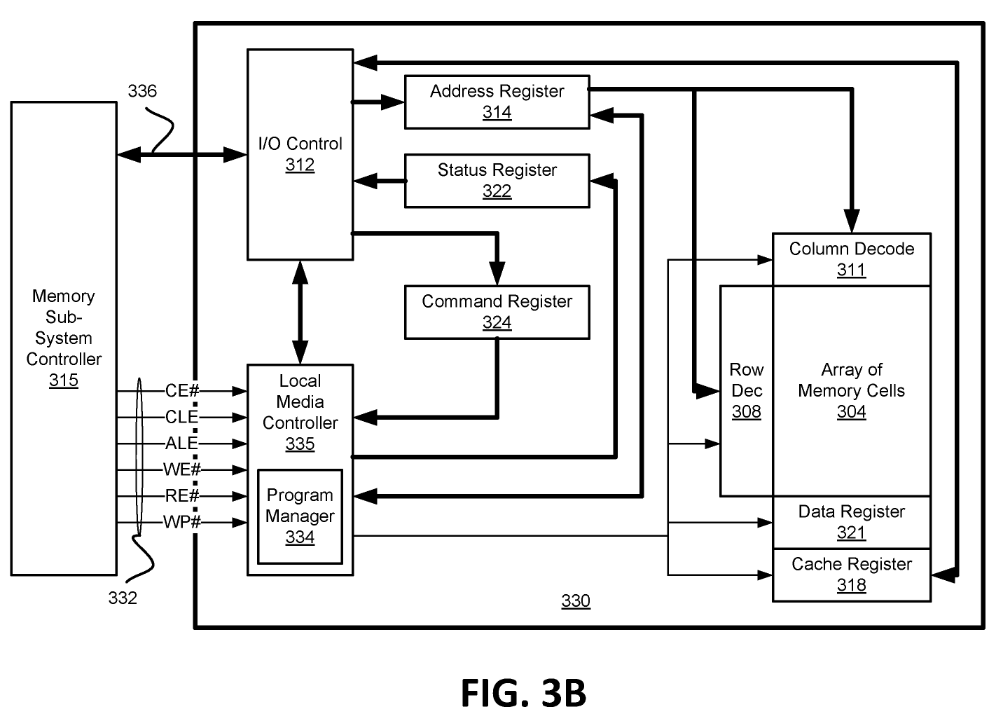

FIG. 3A illustrates an example computing system 300 that includes a memory sub-system 310 in accordance with some embodiments of the present disclosure. In some embodiments, one or more components of computing system 300 include conductive lines manufactured according to a method described herein above. The memory sub-system 310 can include media, such as one or more volatile memory devices (e.g., memory device 340), one or more non-volatile memory devices (e.g., memory device 330), or a combination of such.

A memory sub-system 310 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 300 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 300 can include a host system 320 that is coupled to one or more memory sub-systems 310. In some embodiments, the host system 320 is coupled to multiple memory sub-systems 310 of different types. FIG. 3A illustrates one example of a host system 320 coupled to one memory sub-system 310. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 320 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 320 uses the memory sub-system 310, for example, to write data to the memory sub-system 310 and read data from the memory sub-system 310.

The host system 320 can be coupled to the memory sub-system 310 via a physical host interface. Examples of a physical host interface include a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 320 and the memory sub-system 310. The host system 320 can further utilize an NVM Express (NVMe) interface to access components (e.g., memory devices 330) when the memory sub-system 310 is coupled with the host system 320 by the physical host interface (e.g., PCIe bus). The physical host interface can provide an interface for passing control, address, data, and other signals between the memory sub-system 310 and the host system 320. FIG. 3A illustrates a memory sub-system 310 as an example. In general, the host system 320 can access multiple memory sub-systems via a same communication connection, multiple separate communication connections, and/or a combination of communication connections.

The memory devices 330, 340 can include any combination of the different types of non-volatile memory devices and/or volatile memory devices. The volatile memory devices (e.g., memory device 340) can be random access memory (RAM), such as dynamic random access memory (DRAM) and synchronous dynamic random access memory (SDRAM).

Some examples of non-volatile memory devices (e.g., memory device 330) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 330 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 330 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 330 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 330 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 315 (or controller 315 for simplicity) can communicate with the memory devices 330 to perform operations such as reading data, writing data, or erasing data at the memory devices 330 and other such operations. The memory sub-system controller 315 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 315 can be a microcontroller, special purpose logic circuitry (e.g., a field programmable gate array (FPGA), an application specific integrated circuit (ASIC), etc.), or other suitable processor.

The memory sub-system controller 315 can include a processing device, which includes one or more processors (e.g., processor 317), configured to execute instructions stored in a local memory 319. In the illustrated example, the local memory 319 of the memory sub-system controller 315 includes an embedded memory configured to store instructions for performing various processes, operations, logic flows, and routines that control operation of the memory sub-system 310, including handling communications between the memory sub-system 310 and the host system 320.

In some embodiments, the local memory 319 can include memory registers storing memory pointers, fetched data, etc. The local memory 319 can also include read-only memory (ROM) for storing micro-code. While the example memory sub-system 310 in FIG. 3A has been illustrated as including the memory sub-system controller 315, in another embodiment of the present disclosure, a memory sub-system 310 does not include a memory sub-system controller 315, and can instead rely upon external control (e.g., provided by an external host, or by a processor or controller separate from the memory sub-system).

In general, the memory sub-system controller 315 can receive commands or operations from the host system 320 and can convert the commands or operations into instructions or appropriate commands to achieve the desired access to the memory devices 330. The memory sub-system controller 315 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 330. The memory sub-system controller 315 can further include host interface circuitry to communicate with the host system 320 via the physical host interface. The host interface circuitry can convert the commands received from the host system into command instructions to access the memory devices 330 as well as convert responses associated with the memory devices 330 into information for the host system 320.

The memory sub-system 310 can also include additional circuitry or components that are not illustrated. In some embodiments, the memory sub-system 310 can include a cache or buffer (e.g., DRAM) and address circuitry (e.g., a row decoder and a column decoder) that can receive an address from the memory sub-system controller 315 and decode the address to access the memory devices 330.

In some embodiments, the memory devices 330 include local media controllers 335 that operate in conjunction with memory sub-system controller 315 to execute operations on one or more memory cells of the memory devices 330. An external controller (e.g., memory sub-system controller 315) can externally manage the memory device 330 (e.g., perform media management operations on the memory device 330). In some embodiments, memory sub-system 310 is a managed memory device, which is a raw memory device 330 having control logic (e.g., local media controller 335) on the die and a controller (e.g., memory sub-system controller 315) for media management within the same memory device package. An example of a managed memory device is a managed NAND (MNAND) device.

The memory sub-system 310 includes a memory interface component 313 that can handle interactions of memory sub-system controller 315 with the memory devices of memory sub-system 310, such as memory device 330. For example, memory interface component 313 can receive data from memory device 330, such as data retrieved in response to a read operation or a write operation. In some examples, the memory sub-system controller 315 can include a processor 317 (processing device) configured to execute instructions stored in local memory 319 for performing the operations described herein.

In some embodiments, memory device 330 includes a program manager 334. In some embodiments, local media controller 335 includes at least a portion of program manager 334 and is configured to perform various memory functions. In some embodiments, the program manager 334 is part of the host system 310, an application, or an operating system. Further details with regards to the operations of program manager 334 are described below. In some embodiments, program manager 334 is implemented on memory device 330 using firmware, hardware components, or a combination of the above.

FIG. 3B is a simplified block diagram of a first apparatus, in the form of a memory device 330, in communication with a second apparatus, in the form of a memory sub-system controller 315 of a memory sub-system (e.g., memory sub-system 310 of FIG. 3A), according to an embodiment. In some embodiments, one or more components of memory device 330 include conductive lines manufactured according to a method described herein above. Some examples of electronic systems include personal computers, personal digital assistants (PDAs), digital cameras, digital media players, digital recorders, games, appliances, vehicles, wireless devices, mobile telephones and the like. The memory sub-system controller 315 (e.g., a controller external to the memory device 330), can be a memory controller or other external host device.

Memory device 330 includes an array of memory cells 304 logically arranged in rows and columns. Memory cells of a logical row are typically connected to the same access line (e.g., a wordline) while memory cells of a logical column are typically selectively connected to the same data line (e.g., a bit line). A single access line can be associated with more than one logical row of memory cells and a single data line can be associated with more than one logical column. Memory cells (not shown in FIG. 3B) of at least a portion of array of memory cells 304 are capable of being programmed to one of at least two target data states.

Row decode circuitry 308 and column decode circuitry 311 are provided to decode address signals. Address signals are received and decoded to access the array of memory cells 304. Memory device 330 also includes input/output (I/O) control circuitry 312 to manage input of commands, addresses and data to the memory device 330 as well as output of data and status information from the memory device 330. An address register 314 is in communication with I/O control circuitry 312 and row decode circuitry 308 and column decode circuitry 311 to latch the address signals prior to decoding. A command register 324 is in communication with I/O control circuitry 312 and local media controller 335 to latch incoming commands.

A controller (e.g., the local media controller 335 internal to the memory device 330) controls access to the array of memory cells 304 in response to the commands and generates status information for the external memory sub-system controller 315, i.e., the local media controller 335 is configured to perform access operations (e.g., read operations, programming operations and/or erase operations) on the array of memory cells 304. The local media controller 335 is in communication with row decode circuitry 308 and column decode circuitry 311 to control the row decode circuitry 308 and column decode circuitry 311 in response to the addresses. In at least one embodiment, local media controller 335 includes program manager 334, which can implement the bad block mapping operations with respect to memory device 330, as described herein.

The local media controller 335 is also in communication with a cache register 318. Cache register 318 latches data, either incoming or outgoing, as directed by the local media controller 335 to temporarily store data while the array of memory cells 304 is busy writing or reading, respectively, other data. During a programming operation (e.g., a write operation), data can be passed from the cache register 318 to the data register 321 for transfer to the array of memory cells 304; then new data can be latched in the cache register 318 from the I/O control circuitry 312. During a read operation, data can be passed from the cache register 318 to the I/O control circuitry 312 for output to the memory sub-system controller 315; then new data can be passed from the data register 321 to the cache register 318. The cache register 318 and/or the data register 321 can form (e.g., can form a portion of) a page buffer of the memory device 330. A page buffer can further include sensing devices (not shown in FIG. 3B) to sense a data state of a memory cell of the array of memory cells 304, e.g., by sensing a state of a data line connected to that memory cell. A status register 322 can be in communication with I/O control circuitry 312 and the local memory controller 335 to latch the status information for output to the memory sub-system controller 315.

Memory device 330 receives control signals at the memory sub-system controller 315 from the local media controller 335 over a control link 332. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 332 depending upon the nature of the memory device 330. In at least one embodiment, memory device 330 receives command signals (which represent commands), address signals (which represent addresses), and data signals (which represent data) from the memory sub-system controller 315 over a multiplexed input/output (I/O) bus 336 and outputs data to the memory sub-system controller 315 over I/O bus 336.

For example, the commands can be received over input/output (I/O) pins [7:0] of I/O bus 336 at I/O control circuitry 312 and can then be written into command register 324. The addresses can be received over input/output (I/O) pins [7:0] of I/O bus 336 at I/O control circuitry 312 and can then be written into address register 314. The data can be received over input/output (I/O) pins [7:0] for an 8-bit device or input/output (I/O) pins [15:0] for a 16-bit device at I/O control circuitry 312 and then can be written into cache register 318. The data can be subsequently written into data register 321 for programming the array of memory cells 304.

In at least one embodiment, cache register 318 can be omitted, and the data can be written directly into data register 321. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 330 by an external device (e.g., the memory sub-system controller 315), such as conductive pads or conductive bumps as are commonly used.

In some implementations, additional circuitry and signals can be provided, and that the memory device 330 of FIG. 3B has been simplified. It should be recognized that the functionality of the various block components described with reference to FIG. 3B cannot necessarily be segregated to distinct components or component portions of an integrated circuit device. For example, a single component or component portion of an integrated circuit device could be adapted to perform the functionality of more than one block component of FIG. 3B. Alternatively, one or more components or component portions of an integrated circuit device could be combined to perform the functionality of a single block component of FIG. 3B. Additionally, while specific I/O pins are described in accordance with popular conventions for receipt and output of the various signals, it is noted that other combinations or numbers of I/O pins (or other I/O node structures) can be used in the various embodiments.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular embodiments may vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method, comprising:
forming a tier stack of an electronic circuit, the tier stack comprising a plurality of tiers, wherein a tier of the plurality of tiers comprises multiple alternating conductive and dielectric layers;
exposing a conductive layer of the tier by etching one or more dielectric layers; and
forming a protective layer on the conductive layer, wherein the conductive layer comprises a metal, and wherein the protective layer comprises the metal.

2. The method of claim 1, further comprising:
performing one or more oxidizing operations or one or more nitridizing operations with respect to the tier stack, wherein the conductive layer is protected during the one or more oxidizing operations or the one or more nitridizing operations by the protective layer.

3. The method of claim 1, further comprising:
patterning a mask material on top of the tier stack, wherein the one or more dielectric layers are etched according to the patterned mask material; and
removing the mask material from the top of the tier stack.

4. The method of claim 1, further comprising:
causing silicon to react with the metal to form a metal-silicide, wherein the protective layer comprises the metal-silicide.

5. The method of claim 4, further comprising:
introducing a silicon-containing precursor to the metal, thus causing the silicon- containing precursor to react with the metal.

6. The method of claim 4, further comprising:
depositing a silicon layer on the metal; and
annealing the silicon layer to cause the silicon to react with the metal.

7. The method of claim 6, further comprising:
removing unreacted silicon from the protective layer.

8. The method of claim 1, wherein the one or more dielectric layers comprise a metalloid oxide layer and a metalloid nitride layer, and wherein the metal comprises molybdenum.

9. The method of claim 1, wherein the plurality of tiers forms a stair-step profile comprising multiple layers of each tier.

10. The method of claim 1, wherein the electronic circuit comprises a memory array, and wherein the plurality of tiers form one or more conductive lines.

11. A method, comprising:
forming a tier stack of an electronic circuit, the tier stack comprising a plurality of tiers, wherein a tier of the plurality of tiers comprises a first layer of dielectric material, a second layer of dielectric material, a third layer of dielectric material, and a fourth layer of conductive material;
exposing the fourth layer of the tier by etching a portion of the first layer, the second layer, and the third layer;
depositing a liner on top of the fourth layer, wherein the fourth layer comprises a metal;
and forming an protective layer by causing the liner to react with the metal, wherein the protective layer comprises the metal.

12. The method of claim 11, further comprising:performing one or more oxidizing operations or one or more nitridizing operations with respect to the tier stack, wherein the fourth layer is protected, by the protective layer, during the one or more oxidizing operations or the one or more nitridizing operations.

13. The method of claim 11, wherein forming the protective layer comprises annealing a material comprising the liner.

14. The method of claim 11, wherein the first layer comprises a metalloid oxide, wherein the second layer comprises a metalloid nitride, and wherein the metal comprises molybdenum.

15. The method of claim 11, wherein the electronic circuit comprises a memory array, and wherein the plurality of tiers form one or more conductive lines.

16. A method, comprising:
forming a tier stack of an electronic circuit, the tier stack comprising a plurality of tiers, wherein a tier of the plurality of tiers comprises a first layer of dielectric material, a second layer of dielectric material, a third layer of dielectric material, and a fourth layer of conductive material;
exposing the fourth layer of the tier by etching a portion of the first layer, the second layer, and the third layer, wherein the fourth layer comprises a metal; and
forming an protective layer by introducing a precursor to the metal, thus causing the precursor to react with the metal, wherein the protective layer comprises the metal.

17. The method of claim 16, further comprising:
performing one or more oxidizing operations or one or more nitridizing operations with respect to the tier stack, wherein the fourth layer is protected during the one or more oxidizing operations or the one or more nitridizing operations by the protective layer.

18. The method of claim 16, wherein the precursor is a silicon-containing precursor.

19. The method of claim 16, wherein the first layer comprises a metalloid oxide, wherein the second layer comprises a metalloid nitride, and wherein the metal comprises molybdenum.

20. The method of claim 16, wherein the electronic circuit comprises a memory array, and wherein the plurality of tiers form one or more conductive lines.
